(19) United States
(12) Patent Application Publication
(10) Pub. No.: US 2025/0274152 A1
(43) Pub. Date: Aug. 28, 2025

(54) Receiver

(71) Applicant: GCT Semiconductor, Inc., San Jose, CA (US)

(72) Inventors: Ji Young CHO, Seoul (KR); Jeong Min KIM, Seoul (KR); Cheol Ung PARK, Seoul (KR)

(21) Appl. No.: 19/058,710

(22) Filed: Feb. 20, 2025

(30) Foreign Application Priority Data
Feb. 22, 2024 (KR) 10-2024-0025661

(51) Int. Cl. H04B 1/10

(52) U.S. Cl. CPC H04B 1/1027

(57) ABSTRACT

The receiver of this embodiment comprises: an I branch mixer that down-converts a radio frequency signal to output an I component and an I branch channelization filter that separates a baseband signal from an output signal of said I branch mixer; and a Q branch mixer that down-converts said RF signal to output a Q component and a Q branch channelization filter that separates a baseband signal from an output signal of said Q branch mixer, a frequency dependent mismatch estimator for calculating a frequency dependent mismatch of said I branch and said Q branch, and a frequency dependent mismatch compensation part for compensating a frequency dependent mismatch of said I branch and said Q branch according to a calculation result of said frequency dependent mismatch estimator.

### CROSS-REFERENCE TO RELATED APPLICATION

This application claims priority to and the benefit of Korean Patent Application No. 10-2024-0025661, filed on Feb. 22, 2024, the disclosure of which is incorporated herein by reference in its entirety.

### BACKGROUND

### Field of the Invention

The present disclosure generally relates to a receiver.

### Discussion of Related Art

A direct conversion receiver uses quadrature mixing to down convert signals in the radio frequency (RF) band to baseband (BB) signals at once. Quadrature mixing uses two mixers to multiply the received signal with two local oscillator (LO) signals that have a 90-degree phase difference. The I and Q signals, which are divided into the I branch and Q branch of the baseband, are processed by the ADC after being converted into discrete-time signal samples through a lowpass filter (LPF) and amplifier.

An ideal receiver operates on the premises of a 90-degree phase difference between the two LO signals, identical gain, and identical frequency characteristics of the LPF, amplifier, and DAC of the two I/Q branches. However, actual semiconductor process forms device-level mismatches that are independent of the design, and this causes the three prerequisites to be not met, resulting in LO phase/gain mismatch and baseband filter mismatch.

The aforementioned receiver mismatch has both frequency-independent and frequency-dependent characteristics, and this IQ mismatch in the receiver acts by adding a conjugate image to the original signal to be received, which degrades the signal-to-noise ratio (SNR) of the received signal and increases the bit error rate (BER) like an interferer.

One of the challenges that present disclosure aims to solve is to provide a technology that can compensate for the two aforementioned mismatches, which are the difficulties of the prior art.

### SUMMARY OF THE INVENTION

According to an aspect of the present disclosure, there is provided a receiver which includes: an I-branch comprising an I-branch mixer that down-converts a radio frequency signal to output an I-component, and an I-branch channelization filter that separates the baseband signal from the output signal of said I-branch mixer; a Q-branch comprising a Q-branch mixer that down-converts the RF signal to output a Q component, and a Q-branch channelization filter for separating a baseband signal from an output signal of the Q-branch mixer; a frequency-dependent mismatch estimation unit that computes the frequency-dependent mismatch of the I branch and the Q branch; and a frequency dependent mismatch compensation unit that compensates for frequency dependent mismatches of the I branch and the Q branch according to a computation result of the frequency dependent mismatch estimation unit.

The frequency dependent mismatch compensation unit may further comprises a compensation filter on the I path having a transfer function corresponding to the transfer function of the I branch channelization filter divided by the transfer function of the Q branch channelization filter.

The frequency dependent mismatch compensation unit may further comprises a delay line on the Q path having a delay corresponding to a delay of said compensation filter.

A transfer function of the compensation filter can be derived by value of time average of time-image correlation of signal output from the channelization filter normalized by average power of the signal output from the channelization filter. And when the value is m(k), a frequency-dependent mismatch estimation unit satisfies the mathematical expression

$$Γ ( k ) = {H}_{D} ( k ) {g}_{RX} {e}^{- j {θ}_{RX}} = \frac{1 - m * ( k )}{1 + m * ( k )} ,$$

wherein an argument angle and an absolute value of the Γ(k) are extrapolated to get the H_{D}(k) and the impulse response h_{D}(n) of the compensation filter is derived from normalized N-point Inverse DFT and applying window.

The frequency-dependent mismatch estimation unit acquires the normalized value of time average of time-image correlation of signal output from the channelization filter normalized by average power of the signal output from the channelization filter by a pilot signal comprising SSB multitone.

According to another aspect of the present disclosure, there is provided a receiver comprising: an I-branch comprising an I-branch mixer that down-converts a radio frequency signal to output an I-component, and an I-branch channelization filter that separates the baseband signal from the output signal of said I-branch mixer; a Q-branch comprising a Q-branch mixer that down-converts the RF signal to output a Q component, and a Q-branch channelization filter that separates a baseband signal from an output signal of the Q-branch mixer; a frequency-independent mismatch estimation unit that computes the frequency-independent mismatch of the I branch and the Q branch; a frequency-independent mismatch compensation unit that compensates for frequency-independent mismatches of the I branch and the Q branch according to a computation result of the frequency-independent mismatch estimation unit.

The frequency-independent mismatch estimator computes a gain mismatch and a phase mismatch of the I-branch mixer and the Q-branch mixer from a time average of the power of the output signals of the I-branch mixer and the Q-branch mixer normalized by a time average of the squared output signals of the I-branch mixer and Q-branch mixer.

The frequency-independence mismatch estimation unit estimates the gain mismatch (g_{RX}) and phase mismatch (θ_{RX}) by computing equation

$$\frac{E [ {x}_{n}^{2} ]}{E [ {\vert {x}_{n} \vert}^{2} ]} = \frac{1 - {g}_{RX}^{2}}{1 + {g}_{RX}^{2}} - j \frac{2 {g}_{RX}}{1 - {g}_{RX}^{2}} sin {θ}_{RX} .$$

xₙ: the output of the mixer in the discrete time domain

The frequency-independent mismatch compensation unit comprises: a first multiplier connected to the I branch, a second multiplier connected to the Q branch, a third multiplier that amplifies the output signal of the first multiplier, and an adder that sums the output of the second multiplier with the output of the third multiplier.

A gain of the first multiplier corresponds to g_{RX}, a gain of the second multiplier corresponds to cos (1/θ_{RX}), a gain of the third multiplier corresponds to tan(θ_{RX}). (g_{RX}: gain mismatch, θ_{RX}: phase mismatch).

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a diagram showing an overview of a real receiver with an error.

FIG. 2 is a drawing showing an overview of the frequency-independent mismatch compensation unit.

FIG. 3 is a diagram showing an overview of the frequency-dependent mismatch compensation unit.

### DETAILED DESCRIPTION OF EXEMPLARY EMBODIMENTS

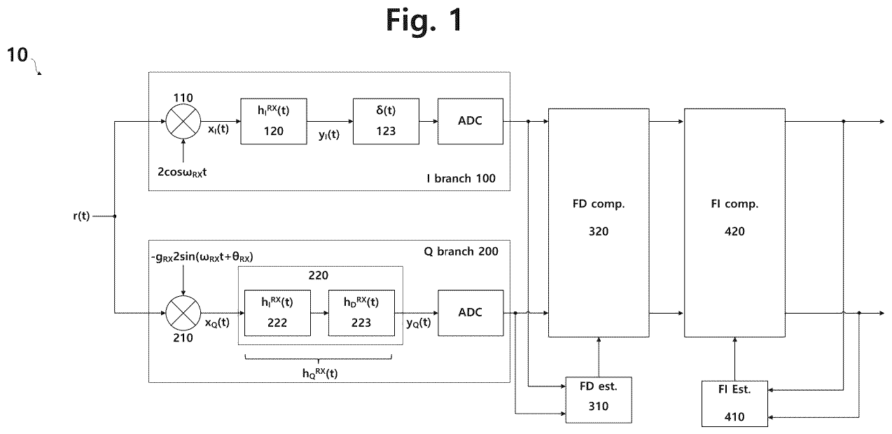

The present embodiments will now be described with reference to the accompanying drawings. FIG. 1 is a diagram illustrating an overview of a realistic receiver 10 with mismatch. Referring to FIG. 1, the receiver 10 of present embodiment includes an I branch 100 comprising an I branch mixer 110 that down converts a radio frequency signal (r(t)) to output an I component, and a Q branch 200 comprising a Q branch mixer 210 that down converts the RF signal (r(t)) to output a Q component.

In one embodiment, the I branch 100 may further include an I branch channelization filter 120 that separates the baseband signal from the output signal of the I branch mixer 110, and the Q branch 200 may further include a Q branch channelization filter 220 that separates the baseband signal from the output signal of the Q branch mixer 210.

The receiver 10 may include a frequency dependent mismatch computation part FD est, 310 that computes the frequency dependent mismatch of the I branch 100 and the Q branch 200, and a frequency dependent mismatch compensation part 320 that compensates for the frequency dependent mismatch of the I branch 100 and the Q branch 200 based on the computation result of the frequency dependent mismatch computation part 310.

Further, in one embodiment of the receiver 10, the receiver 10 may include a frequency-independent mismatch operation part 410 that computes the frequency-independent mismatch of the I branch 100 and the Q branch 200, and a frequency-independent mismatch compensation part 420 that compensates for the frequency-independent mismatch of the I branch 100 and the Q branch 200 based on the result of the computation of the frequency-independent mismatch operation part 410.

In the embodiment shown, the receiver 10 is illustrated as including both the frequency dependent mismatch computation part 310 and the frequency-dependent mismatch compensation unit 320 and the frequency-independent mismatch operation part 410 and the frequency-independent mismatch compensation part 420. However, embodiments of the receiver not shown may include only one of the frequency-dependent mismatch operator and the frequency-dependent mismatch compensator or the frequency-independent mismatch operator and the frequency-independent mismatch compensator.

Referring to FIG. 1, the incoming signal r(t) is bifurcated and input to the I branch 100 and the Q branch 200. The signal r(t) is down-converted by mixing it with a down-conversion signal cos ω_{RX}t at mixer 110 of I branch 100. The signal r(t) is mixed with the down-conversion signal at mixer 210 of Q branch 200 and down-converted.

The down-converted signal XI (t) from the mixer 110 of the I-branch is input to the I-branch channelization filter 120, and the I-branch channelization filter 120 outputs the base band signal y_{I}(t). Time domain impulse response of the I-branch channelization filter 120 may be represented by h_{I}^{RX}(t). The down-converted signal x_{Q}(t) from the mixer 210 of the Q branch is input to the Q branch channelization filter 220. The Q-branch channelization filter 220 outputs a baseband signal y_{Q}(t). Time domain impulse response of the Q-branch channelization filter 220 may be represented as h_{Q}^{RX}(t).

In one embodiment, the I-branch channelization filter 120 and the Q-branch channelization filter 220 may be low pass filters (LPFs). In one embodiment, the outputs of the I-branch channelization filter 120 and the Q-branch channelization filter 220 may be provided to an analog-to-digital converter (ADC). In one embodiment, the I branch 100 may further include a delay line 123 that delays with a corresponding delay time to match the delay of the Q branch 200. The outputs of the I-branch channelization filter 120 and the Q-branch channelization filter 220 may be provided to an analog-to-digital converter (ADC).

Ideally, the signals provided to each mixer by the local oscillator for down-conversion have the same amplitude. Also, ideally, the signal provided to the mixer 110 of the I branch and the signal provided to the mixer 210 of the Q branch have a phase difference of 90 degrees.

However, in practice, there are differences in the signal magnitudes provided by the local oscillator (LO), and the signals provided are not exactly 90 degrees out of phase. In this case, the mismatch in signal magnitude is denoted as gain mismatch g_{RX} and the mismatch in phase is denoted as θ_{RX}. However, the gain and phase mismatch of the mixer in down conversion may not be shown separately because they are indistinguishable from the mismatch of the LO. As we will see later, gain and phase mismatches are time (and frequency) independent.

The mismatched signal provided to the mixer, L_{RX} (t), is represented by the equation below.

$$\begin{matrix}{L}_{R X} ( t ) = 2 cos {ω}_{R X} t - {jg}_{R X} 2 sin ( {ω}_{R X} t + {θ}_{R X} ) \\ = ( 1 + {g}_{RX} {e}^{- j {θ}_{RX}} ) {e}^{- j {ω}_{RX} t} + ( 1 - {g}_{R X} {e}^{+ j {θ}_{R X}} ) {e}^{+ j {ω}_{R X} t}\end{matrix} \qquad [ Equation 3 ]$$

(L_{RX} (t): LO signal, g_{RX}: gain mismatch, θ_{RX}: phase mismatch, ω_{RX}: down converted signal frequency)

Down-converted output signal x(t) by an LO signal containing the mismatch is represented by the equation below.

$$\begin{matrix}x ( t ) = LPF [ r ( t ) \cdot {L}_{RX} ( t ) ] \\ = \frac{1 + {g}_{R X} {e}^{- j {θ}_{R X}}}{2} \cdot {r}_{B B} ( t ) + \frac{1 - {g}_{R X} {e}^{+ j {θ}_{RX}}}{2} \cdot {r}_{BB}^{*} ( t ) \\ = α \cdot {r}_{B B} ( t ) + β \cdot {r}_{BB}^{*} ( t )\end{matrix} \qquad [ Equation 4 ]$$

(x(t): Output signal from the mixer, r_{BB}(t): The received signal converted to the baseband, r*_{BB} (t): Complex conjugate of the received signal converted to the baseband)

Equation 4 can be summarized in the frequency domain as Equation 5 below.

$$\begin{matrix}X ( f ) = \frac{1 + {g}_{R X} {e}^{- j {θ}_{RX}}}{2} \cdot {R}_{B B} ( f ) + \frac{1 - {g}_{R X} {e}^{+ j {θ}_{RX}}}{2} \cdot {R}_{BB}^{*} ( f ) \\ = α \cdot {R}_{B B} ( f ) + β \cdot {R}_{BB}^{*} ( f )\end{matrix} \qquad [ Equation 5 ]$$

(α, β: constants)

In the ideal case, where there is no effect of mismatch, g_{RX} is 1 and θ_{RX} is 0. Consequently, the value of β is 0. The transmit frequency ω_{TX} and the receive frequency ω_{RX} are equal, resulting in a baseband signal r_{BB}(t). However, if gain mismatch and phase mismatch occur, the value of β is not zero, and we can see that the IQ mismatch generates an additional component r*_{BB} (t), which is the conjugate image of the unintended r_{BB} (t) signal.

The resulting conjugate image, r*_{BB} (t), acts as an interfering signal to the desired signal, degrading the signal-to-noise ratio and reception performance of the receiver. Furthermore, when viewed in the frequency domain, the coefficients of the desired signal r_{BB} (t) and its conjugate image, α, β, are constant and not a function of frequency, as exemplified by Equation 5. In this sense, it can be called a frequency-independent IQ mismatch.

The mismatch of the filters h^{RX}_{I} (t), h^{RX}_{Q} (t) of the baseband I branch 100 and Q branch 200 includes differences in pole, zero, and propagation delays just prior to the ADC sample and hold due to circuit elements in the semiconductor process implementing the anti-aliased low-pass filter of the analog baseband.

When the baseband filter has an IQ mismatch, the input and output of the filter stage satisfy Equation 6 below.

$$\begin{matrix}y ( t ) = \frac{{h}_{I}^{R X} ( t ) + {h}_{Q}^{RX} ( t )}{2} ⊗ x ( t ) + \frac{{h}_{I}^{R X} ( t ) - {h}_{Q}^{RX} ( t )}{2} ⊗ {x}^{*} ( t ) \\ = {h}_{e}^{R X} ( t ) ⊗ x ( t ) + {h}_{o}^{R X} ( t ) ⊗ {x}^{Y} ( t ) \\ Y ( f ) = {H}_{e}^{R X} ( f ) \cdot X ( f ) + {H}_{o}^{R X} ( f ) \cdot {X}^{*} ( - f ) \\ ( {h}_{e}^{R X} ( t ) = \frac{{h}_{I}^{R X} ( t ) + {h}_{Q}^{R X} ( t )}{2} , \\ {h}_{o}^{R X} ( t ) = \frac{{h}_{I}^{R X} ( t ) - {h}_{Q}^{R X} ( t )}{2} )\end{matrix} \qquad [ Equation 6 ]$$

(xᵢ(t): Output signal of the I branch mixer, x_{Q}(t): Output signal of the Q-branch mixer, x(t)=xᵢ(t)+j·x_{Q}(t), hᵢ^{RX}(t): Impulse response of the I-branch channelization filter, hQ^{RX}(t): Impulse response of the Q-branch channelization filter, \textcircled{x}: Convolution operation)

From Equation 6, we can see that the desired signal, x(t), is not transmitted as is, but the conjugate image, x*(t), is added. Looking at this in the frequency domain, the target signal and the coefficients Hₑ^{RX}(f), Hₒ^{RX}(f) of the conjugate image are a function of frequency, and the interference from the image is also a function of frequency. In this sense, we can call this a frequency-dependent IQ mismatch.

From this, when the IQ mismatch of the LO, the mixer, and the IQ mismatch of the baseband branch are obtained, the demodulated signal y(t) can be represented as shown in Equation 7 below. By mismatching the I branch 100 and Q branch 200 of the receiving end 10, a complex conjugate term is generated in the output signal as shown in Equation 6, from which an image is formed in the frequency domain.

$$\begin{matrix}y ( t ) = {h}_{e}^{RX} ( t ) ⊗ x ( t ) + {h}_{o}^{RX} ( t ) ⊗ {x}^{*} ( t ) \\ = {h}_{e}^{RX} ( t ) ⊗ \{ \frac{1 + {g}_{RX} {e}^{- j {θ}_{RX}}}{2} \cdot {r}_{BB} ( t ) + \frac{1 + {g}_{RX} {e}^{j {θ}_{RX}}}{2} \cdot {r}_{BB}^{*} ( t ) \} + {h}_{o}^{RX} ( t ) ⊗ \{ \frac{1 + {g}_{RX} {e}^{+ j {θ}_{RX}}}{2} \cdot {r}_{BB}^{*} ( t ) + \frac{1 - {g}_{RX} {e}^{- j {θ}_{RX}}}{2} \cdot {r}_{BB} ( t ) \} \\ = \frac{{h}_{I}^{RX} ( t ) + {g}_{RX} {e}^{- j {θ}_{RX}} {h}_{Q}^{RX} ( t )}{2} ⊗ {r}_{BB} ( t ) + \frac{{h}_{I}^{RX} ( t ) + {g}_{RX} {e}^{+ j {θ}_{RX}} {h}_{Q}^{RX} ( t )}{2} ⊗ {r}_{BB}^{*} ( t ) \\ = {g}_{1}^{RX} ( t ) ⊗ {r}_{BB} ( t ) + {g}_{2}^{RX} ( t ) ⊗ {r}_{BB}^{*} ( t ) \\ Y ( f ) = {G}_{1}^{RX} ( f ) ⊗ {R}_{BB} ( f ) + {G}_{2}^{RX} ( f ) ⊗ {R}_{BB}^{*} ( - f )\end{matrix} \qquad [ Equation 7 ]$$

In Equation 7, taking H_{I}^{RX} (f) in common, H_{D}^{RX} (f)=H_{Q}^{RX} (f)/H_{I}^{RX} (f), which is expressed as the ratio of the transfer function of the Q-branch channelization filter to the transfer function of the I-branch channelization filter. Thus, the channelization filter 220 of the Q branch can be represented as a cascade connection of filters h_{D}^{RX} (t), 223 representing the I branch channelization filter 120 and the variation of the Q branch channelization filter 222 with respect to the I branch channelization filter 120 in the time domain, as exemplified in FIG. 1. The above equation 7 is summarized as follows.

$$\begin{matrix}Y ( f ) = {H}_{I}^{R X} ( f ) \{ \frac{1 + {g}_{RX} {e}^{- j {θ}_{RX}} {H}_{D}^{R X} ( f )}{2} \cdot {R}_{BB} ( f ) + \frac{1 - {g}_{R X} {e}^{j {θ}_{R X}} {H}_{D}^{R X} ( f )}{2} \cdot {R}_{BB}^{*} ( - f ) \} \\ = {H}_{I}^{R X} ( f ) {Y}^{′} ( f ) \\ {Y}^{′} ( f ) = \frac{1 + {g}_{RX} {e}^{- j {θ}_{RX}} {H}_{D}^{R X} ( f )}{2} \cdot {R}_{BB} ( f ) + \frac{1 - {g}_{RX} {e}^{j {θ}_{RX}} {H}_{D}^{R X} ( f )}{2} \cdot {R}_{BB}^{*} ( - f ) \\ = {G}_{1}^{RX} ( f ) {R}_{BB} ( f ) + {G}_{2}^{R X} {R}_{BB}^{*} ( - f )\end{matrix}$$

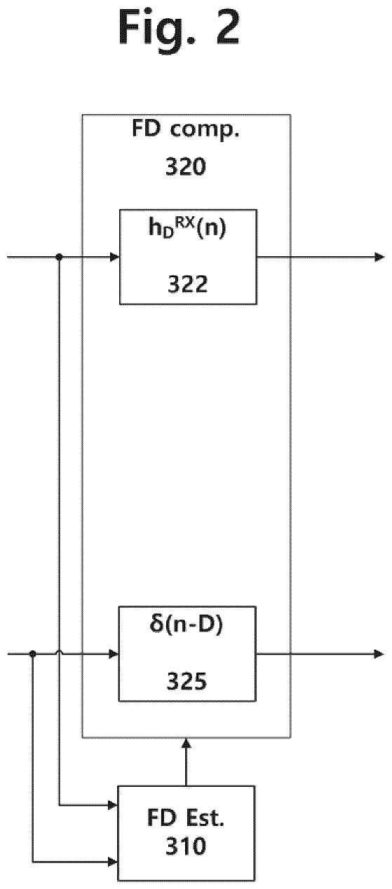

A system model can be considered that includes a frequency-independent mismatch compensation unit 410 that includes a frequency-dependent mismatch compensation filter 322 with H_{I}^{RX}(f) common to the I and Q branches, and a frequency-independent mismatch compensation filter 322 with a transfer function of H_{D}^{RX} (f)=H_{Q}^{RX}(f)/H_{I}^{RX}(f) for the Q branch only. This can be represented as shown in FIG. 2 using a discrete time domain h_{D}^{RX}(n). h_{D}^{RX}(t) can be summarized as shown in Equation 9 below, from which the mismatch between the baseband filters of the IQ branch can be expressed.

$${h}_{D}^{R X} ( t ) = {F}^{- 1} ( {H}_{D}^{R X} ( f ) ) = {F}^{- 1} ( \frac{{H}_{Q}^{R X} ( f )}{{H}_{I}^{R X} ( f )} ) \to {h}_{D}^{R X} ( n ) \qquad [ Equation 9 ]$$

The mismatch between the IQ branch baseband filters is represented by H_{D}^{RX}(f) in the Q branch, and we add H_{D}^{RX} (f) in the I branch to compensate for it. To implement this, after AD sampling, we compensate by placing a discrete-time version of h_{D}^{RX}(t), h_{D}^{RX}(n), on the I branch. Since h_{D}^{RX}(n) is an infinite impulse response (IIR), we use the finite impulse response (FIR) approximation for practical implementation. The Q branch includes a tapped-delay-line 325, which balances the integer group delay D of h_{D}^{RX} (n). This allows us to compensate for the receive frequency dependent IQ mismatch.

The conversion expressions for the complex envelopes of the gain mismatch and phase mismatch derived by Equation 4 and Equation 5 can be obtained as shown in Equation 10 below, which can be used to obtain the matrix form of the IQ vector as shown in Equation 11. (z(t)=r_{BB} (t))

$$\begin{matrix}{x}_{i} ( t ) = \frac{x ( t ) + {x}^{*} ( t )}{2} = \frac{1}{2} \{ z ( t ) + z * ( t ) \} = {z}_{i} ( t ) \\ {{X}_{q ( t )} = \frac{x ( t ) - {x}^{*} ( t )}{2 j} = \frac{{g}_{RX}}{2 j} \{ z ( t ) {e}^{- j {θ}_{RX}} - {z}^{*} ( t ) e )}^{j {θ}_{RX}} \} \\ = {g}_{RX} {z}_{i} ( t ) \frac{{e}^{- j {θ}_{RX}} - {e}^{j {θ}_{RX}}}{2 j} + {g}_{RX} {z}_{q} ( t ) \frac{{e}^{j {θ}_{RX}} + {e}^{- j {θ}_{RX}}}{2} \\ = {g}_{RX} sin {θ}_{{RX}^{Z} i} ( t ) + {g}_{RX} cos {θ}_{RX} {z}_{q} ( t )\end{matrix} \qquad [ Equation 10 ]$$

$$[ \begin{matrix}{Z}_{i} ( t ) \\ {Z}_{q} ( t )\end{matrix} ] = \frac{1}{{g}_{RX}} [ \begin{matrix}1 & 0 \\ tan {θ}_{R X} & \frac{1}{cos {θ}_{RX}}\end{matrix} ] [ \begin{matrix}{g}_{RX} & 0 \\ 0 & 1\end{matrix} ] [ \begin{matrix}{x}_{i} ( t ) \\ {x}_{q} ( t )\end{matrix} ] \qquad [ Equation 11 ]$$

By matrixing Equation 10 and finding its inverse, we get Equation 11, which can be used to compensate for the gain mismatch and phase mismatch of the receiver LO.

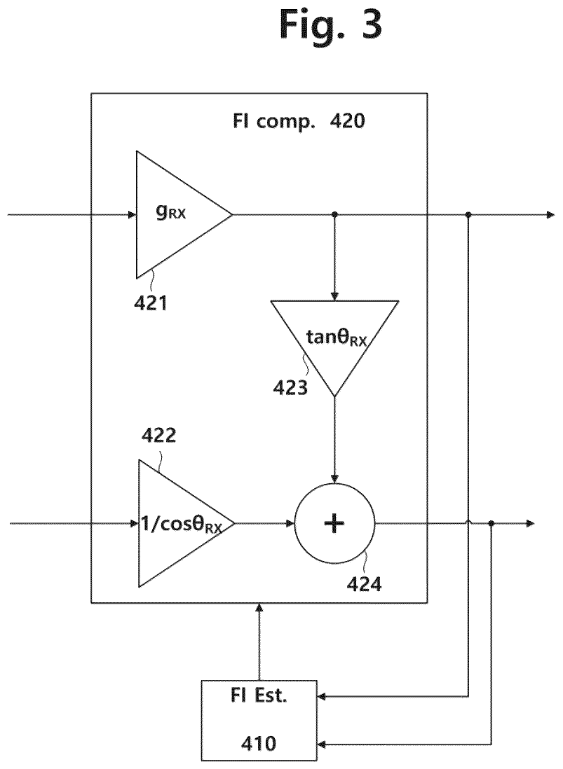

FIG. 3 is a diagram illustrating an overview of a frequency-independent mismatch compensation unit 420. Referring to FIG. 3, the frequency-independent mismatch compensation section 410 includes a first multiplier 421 connected to the I branch, a second multiplier 422 connected to the Q branch, a third multiplier 423 that performs a multiplicative operation on the output signal of the first multiplier, and an adder 424 that sums the output of the second multiplier 422 and the output of the third multiplier 423.

The frequency-independent mismatch compensation unit 410, shown in FIG. 3, implements Equation 11, wherein the gain of the first multiplier 421 included in the frequency-independent mismatch compensation unit 420 corresponds to g_{RX}. The gain of the second multiplier 422 corresponds to cos (1/θ_{RX}). In one embodiment, cos (1/θ_{RX}) can be approximated as 1+(θ_{RX}²)/2 using a Taylor series expansion and taken as the gain of the second multiplier 422.

The gain of the third multiplier corresponds to tan(θ_{RX}). In one embodiment, tan(θ_{RX}) can be approximated as θ_{RX}+(θ_{RX}²)/3 using a Taylor series expansion, which can be taken as the gain of the third multiplier 423. In this way, the frequency-independent mismatch can be compensated for to obtain mismatch-compensated received signals r_{I} and r_{Q}.

To compensate for the frequency-independent IQ mismatch, we need to estimate the values of the IQ gain mismatch, g_{RX}, and the IQ phase mismatch, θ_{RX}, of the LO and mixer circuits. In Equation 4 above, when the N-point normalized DFT of the discrete-time signal x(n) sampled at signal x(t) is called X(k), (−N/2≤k≤N/2−1), the kth frequency component X(k) contains the complex conjugate R*(−k) of the −kth frequency component, which is the conjugate image, in addition to the kth frequency component R(k) of the original signal.

Since X(k)=αR(k)+βR*(−k), and X(−k)=αR(−k)+βR* (k), the time average of the product of X(k) and X(−k) is equal to Equation 12 below.

$$\begin{matrix}E [ X ( k ) X ( - k ) ] = α β E [ {\vert R ( k ) \vert}^{2} ] + & α β E [ {\vert R ( - k ) \vert}^{2} ] \\ = 2 α β E [ {\vert R ( k ) \vert}^{2} ] & \frac{E [ X ( k ) X ( - k ) ]}{E [ {\vert R ( k ) \vert}^{2} ]} \\ = 2 α β & \end{matrix} \qquad [ Equation 12 ]$$

In Equation 12, R(k) and R(−k) are uncorrelated and E[R(k)]=0 for thermal noise and typical signals, so Equation 12 is rewritten as Equation 13.

$$\begin{matrix}E [ X ( k ) X ( - k ) ] = 2 αβ E [ {\vert R ( k ) \vert}^{2} ] + αβ E [ {\vert R ( - k ) \vert}^{2} ] \\ = 2 αβ E [ {\vert R ( k ) \vert}^{2} ] \frac{E [ X ( k ) X ( - k ) ]}{E [ {\vert R ( k ) \vert}^{2} ]} \\ = 2 αβ\end{matrix} . \qquad [ Equation 13 ]$$

The relationship between the expectation values for the power of the signal before and after being affected by the IQ mismatch is shown in Equation 14 below.

$$\begin{matrix}E [ {\vert X ( k ) \vert}^{2} ] = E [ X ( k ) {X}^{*} ( k ) ] \\ = E [ \{ α R ( k ) + β {R}^{*} ( - k ) \} \{ {α}^{*} {R}^{*} ( k ) + {β}^{*} R ( - k ) \} ] \\ = ( {αα}^{*} + {ββ}^{*} ) E [ {\vert R ( k ) \vert}^{2} ]\end{matrix} . \qquad [ Equation 14 ]$$

From the above two equations, we can obtain metrics to estimate the IQ signal gain mismatch and phase mismatch of the receiver LO and mixer, g_{RX}, θ_{RX}, as shown in Equation 15 below.

$$\begin{matrix}\frac{E [ X ( k ) X ( - k ) ]}{E [ {\vert R ( k ) \vert}^{2} ]} = \frac{2 αβ}{{αα}^{*} + {ββ}^{*}} = \frac{2}{1 + {{g}_{RX}}^{2}} ( \frac{1 - {g}_{RX}}{2} - {{jg}_{RX}}^{2} sin {θ}_{RX} ) \\ = \frac{1 - {{g}_{RX}}^{2}}{1 + {{g}_{RX}}^{2}} - j \frac{2 {g}_{RX}}{1 + {{g}_{RX}}^{2}} sin {θ}_{RX} \\ = A + jB\end{matrix} . \qquad [ Equation 15 ]$$

That is, the gain mismatch component, g_{RX}, and the phase mismatch component, θ_{RX}, of the mixer can be obtained by normalizing the time-averaged E[|xn|²] of the power of the mixer's output signal to the time-averaged E[xn²] of the squared output signal of the mixer. This estimation metric can be called a blind estimation metric because it can work for any received signal r_{BB} (t) without any special conditions and does not require a separate pilot signal.

If X(k) is an ergodic process as described above, then the time average E[X(k)X(−k)] should be equal to the ensemble average, and the fact that the ensemble average calculation of X(k)X(−k) is equal to the time average, as shown in Equation 16 below, indicates that X(k) is an ergodic process. Therefore, the ensemble mean can be used as an estimator for the time mean.

$$\begin{matrix}\frac{1}{N} {\sum }_{k = - N / 2}^{\frac{N}{2} - 1} X ( k ) X ( - k ) = \frac{1}{N} {\sum }_{k = - \frac{N}{2}}^{\frac{N}{2} - 1} \{ {α}^{2} R ( k ) R ( - k ) + {β}^{2} {R}^{*} ( - k ) {R}^{*} ( k ) \} + \frac{1}{N} {\sum }_{k = - \frac{N}{2}}^{\frac{N}{2} - 1} αβ \{ R ( k ) {R}^{*} ( k ) + {R}^{*} ( - k ) R ( - k ) \} \\ \approx 2 αβ \frac{1}{N} {\sum }_{k = - \frac{N}{2}}^{\frac{N}{2} - 1} {\vert R ( k ) \vert}^{2} \frac{1}{N} {\sum }_{k = \frac{- N}{2}}^{\frac{N}{2} - 1} {\vert X ( k ) \vert}^{2} \\ \approx ( {αα}^{*} + {ββ}^{*} ) \frac{1}{N} {\sum }_{k = - \frac{N}{2}}^{\frac{N}{2} - 1} {\vert R ( k ) \vert}^{2}\end{matrix} \qquad [ Equation 16 ]$$

The estimated metric described above is the ensemble mean of the tone-image correlation. However, the ensemble mean of the tone-image correlation is summarized by the following mathematical expression.

$$\begin{matrix}\frac{1}{N} {\sum }_{k = - \frac{N}{2}}^{\frac{N}{2} - 1} X ( k ) X ( - k ) = \frac{1}{N} {\sum }_{l = 0}^{N - 1} X ( 1 ) X ( N - 1 ) \\ = \frac{1}{N} {\sum }_{k = 0}^{N - 1} \frac{1}{\sqrt{N}} {\sum }_{n = 0}^{N - 1} {x}_{n} {e}^{- j \frac{2 π kn}{N}} \cdot \frac{1}{\sqrt{N}} {\sum }_{m = 0}^{N - 1} {x}_{m} {e}^{j \frac{2 π km}{N}} \\ = \frac{1}{{N}^{2}} {\sum }_{n = 0}^{N - 1} {x}_{n} {\sum }_{m = 0}^{N - 1} {x}_{m} {\sum }_{k = 0}^{N - 1} {e}^{j \frac{2 π k ( m - n )}{N}} = \frac{1}{{N}^{2}} {\sum }_{n = 0}^{N - 1} {x}_{n} {\sum }_{m = 0}^{N - 1} {x}_{m} \cdot {δ}_{nm} \\ = \frac{1}{N} {\sum }_{n = 0}^{N - 1} {{x}_{n}}^{2} \\ = E [ {{x}_{n}}^{2} ]\end{matrix} . \qquad [ Equation 17 ]$$

The mean of the signal squared provides an estimation metric as shown in Equation 18 below.

$$\begin{matrix}E [ {{x}_{n}}^{2} ] = \frac{1}{N} {\sum }_{n = 0}^{N - 1} {{x}_{n}}^{2} \\ = \frac{1}{N} ( {α}^{2} {\sum }_{n = 0}^{N - 1} {{r}_{n}}^{2} + {β}^{2} {\sum }_{n = 0}^{N - 1} {{r}_{n}}^{* 2} + 2 αβ {\sum }_{n = 0}^{N - 1} {r}_{n} {{r}_{n}}^{*} ) \\ \approx 2 αβ \frac{1}{N} {\sum }_{n = 0}^{N - 1} {\vert {r}_{n} \vert}^{2} = 2 αβ \cdot E [ {\vert {r}_{n} \vert}^{2} ]\end{matrix} \qquad [ Equation 18 ]$$

The power of the signal before and after contamination by IQ mismatch satisfies Equation 19 below.

$$\begin{matrix}E [ {\vert {x}_{n} \vert}^{2} ] = E [ {x}_{n} {{x}_{n}}^{*} ] \\ = E [ ( α {r}_{n + β {{r}_{n}}^{*}} ) ( {α}^{*} {{r}_{n}}^{* + β *} {r}_{n} ) ] \\ = ( {αα}^{*} + {ββ}^{*} ) E [ {\vert {r}_{n} \vert}^{2} ]\end{matrix} . \qquad [ Equation 19 ]$$

From the two equations, we can obtain metrics to estimate the IQ gain mismatch and phase mismatch, g_{RX}, θ_{RX}, using only the time-domain signal xₙ after contamination by the IQ mismatch.

$$\begin{matrix}\frac{E [ {{x}_{n}}^{2} ]}{E [ {\vert {x}_{n} \vert}^{2} ]} = \frac{2 αβ}{{αα}^{*} + {ββ}^{*}} = \frac{2}{1 + {{g}_{RX}}^{2}} ( \frac{1 - {{g}_{RX}}^{2}}{2} - {jg}_{RX} sin {θ}_{RX} ) \\ = \frac{1 - {{g}_{RX}}^{2}}{1 + {{g}_{RX}}^{2}} - j \frac{2 {g}_{RX}}{1 - {{g}_{RX}}^{2}} sin {θ}_{RX} \\ = A + jB\end{matrix} \qquad [ Equation 20 ]$$

To compensate for the frequency-dependent IQ mismatch as described above, we need to estimate h_{D}^{RX}(n), which is the discrete version of h_{D}^{RX}(t). Estimate h_{D}^{RX}(n) from the signal y(t) output by the channelization filter under the influence of the conjugate image. Let the discrete signal sample of signal y(t) be called y(n), and the N-point normalized DFT of y(n) be called Y(k), where Y(k) satisfies the relationship in Equation 21 according to the continuous-time version of the equation described above.

$$Y ( k ) = {{G}_{1}}^{RX} ( k ) {R}_{BB} ( k ) + {{G}_{2}}^{RX} ( k ) {{R}_{BB}}^{*} ( - k ) . \qquad [ Equation 21 ]$$

$$Y ( - k ) = {{G}_{1}}^{RX} ( - k ) {R}_{BB} ( - k ) + {{G}_{2}}^{RX} ( - k ) {{R}_{BB}}^{*} ( k )$$

If we input a single-sideband (SSB) multitone that fills the positive half of the frequency bin of the N-point DFT as the pilot signal, then R_{BB} (−k)=R_{BB}* (−k)=0 and the equation is summarized as Eq. 22.

$$Y ( k ) = {{G}_{1}}^{RX} ( k ) {R}_{BB} ( k ) = \frac{1 + {g}_{RX} {e}^{- j {θ}_{RX}} {{H}_{D}}^{*} ( k )}{2} \cdot {R}_{BB} ( k ) . \qquad [ Equation 22 ]$$

$$Y ( - k ) = {{G}_{2}}^{RX} ( k ) {{R}_{BB}}^{*} ( k ) = \frac{1 - {g}_{RX} {e}^{+ j {θ}_{RX}} {{H}_{D}}^{*} ( - k )}{2} \cdot {{R}_{BB}}^{*} ( k )$$

Define m(k) as the time average of the tone-image correlation Y(k)Y(−k) normalized by the average power of Y(k), as shown below.

$$E [ Y ( k ) Y ( - K ) ] = {{G}_{1}}^{RX} ( k ) {{G}_{2}}^{RX} ( - k ) \cdot E [ {\vert {R}_{BB} ( k ) \vert}^{2} ] . \qquad [ Equation 23 ]$$

$$E [ {\vert Y ( k ) \vert}^{2} ] = {{G}_{1}}^{RX} ( k ) \overline{{{G}_{1}}^{RX} ( k )} \cdot E [ {\vert {R}_{BB} ( k ) \vert}^{2} ]$$

$$m ( k ) = \frac{E [ Y ( ( k ) Y ( - K ) ]}{E [ {\vert Y ( k ) \vert}^{2} ]} = \frac{{{G}_{2}}^{RX} ( - k )}{\overline{{{G}_{1}}^{RX} ( k )}} = \frac{1 - {g}_{RX} {e}^{+ j {θ}_{RX}} {{H}_{D}}^{*} ( k )}{\overline{1 + {g}_{RX} {e}^{- j {θ}_{RX}} {{H}_{D}}^{*} ( k )}}$$

Since h_{D}(n) is the real filter in Equation 23, applying the conjugate symmetry theorem H_{D} (−k)=H_{D}* (k), we can calculate H_{D} (k)g e_{RX}^{-jθRX} as shown in Equation 24 below.

$$m ( k ) = \frac{1 - {g}_{RX} {e}^{+ j {θ}_{RX}} {{H}_{D}}^{*} ( k )}{1 + {g}_{RX} {e}^{+ j {θ}_{RX}} {{H}_{D}}^{*} ( k )} = \frac{1 - Γ ( k )}{1 + Γ ( k )} \qquad [ Equation 24 ]$$

$$Γ ( k ) = {H}_{D} ( k ) {g}_{RX} {e}^{- j {θ}_{RX}} = \frac{1 - {m}^{*} ( k )}{1 + {m}^{*} ( k )} ,$$

=Since we have entered a positive short-sideband (SSB) multitone, the calculation of m(k) is only valid in the interval 1≤k≤(N/2−1) (E[|Y(k)|²]=0 for −N/2≤k≤0). However, by the conjugate symmetry theorem H_{D} (−k)=H_{D}* (k), the argument angle (arg) of H_{D} (0) is zero, so θ_{RX}=−arg{Γ(0)}. However, we cannot compute Γ(0) directly, so we estimate it by extrapolating arg{Γ(k)}.

Also, the LO gain mismatch g_{RX} is included in H_{D} (k) and does not need to be found separately, but if it is the mismatch of the low-pass filter, we can find it as g_{RX}=|Γ(0)| since |H_{D} (0)|=1. Similarly, we estimate |Γ(k)| by extrapolation. H_{D} (k) on the sphere −N/2≤k≤0 can be filled in using the conjugate symmetry theorem.

Having thus estimated H_{D} (k) for the −N/2≤k≤N/2−1 window, we can take the N-point normalized IDFT and apply a suitable window to obtain the compensated FIR filter hD(n), which is expressed mathematically as Equation 24 below.

$${h}_{D} = NIDFT \{ {H}_{D} ( k ) \} \cdot w ( n ) . \qquad [ Equation 24 ]$$

In other words, the ratio of the time average of the correlation operation of the signal and the image to the average power of the signal at each discrete frequency position gives the mismatch and phase mismatch in the filter at each frequency position.

Although the present invention has been described with reference to the embodiments illustrated in the drawings to help understanding thereof, these are merely exemplary embodiments for implementation, and those skilled in the art will understand that various modifications and equivalent other embodiments are possible therefrom. Accordingly, the true technical scope of the present invention is to be determined by the spirit of the appended claims.

What is claimed is:

1. A receiver comprising:
an I-branch comprising an I-branch mixer that down-converts a radio frequency signal to output an I-component, and an I-branch channelization filter that separates the baseband signal from the output signal of said I-branch mixer;
a Q-branch comprising a Q-branch mixer that down-converts the RF signal to output a Q component, and a Q-branch channelization filter for separating a baseband signal from an output signal of the Q-branch mixer;
a frequency-dependent mismatch estimation unit that computes the frequency-dependent mismatch of the I branch and the Q branch; and
a frequency dependent mismatch compensation unit that compensates for frequency dependent mismatches of the I branch and the Q branch according to a computation result of the frequency dependent mismatch estimation unit.

2. The receiver of claim 1, wherein the frequency dependent mismatch compensation unit further comprises a compensation filter on the I path having a transfer function corresponding to the transfer function of the I branch channelization filter divided by the transfer function of the Q branch channelization filter.

3. The receiver of claim 2, wherein the frequency dependent mismatch compensation unit further comprises a delay line on the Q path having a delay corresponding to a delay of said compensation filter.

4. The receiver of claim 1, wherein a transfer function of the compensation filter is derived by value of time average of time-image correlation of signal output from the channelization filter normalized by average power of the signal output from the channelization filter.

5. The receiver of claim 4,
when the value is m(k), a frequency-dependent mismatch estimation unit satisfies the mathematical expression
$$Γ ( k ) = {H}_{D} ( k ) {g}_{RX} {e}^{- j {θ}_{RX}} = \frac{1 - {m}^{*} ( k )}{1 + {m}^{*} ( k )} ,$$
wherein an argument angle and an absolute value of the Γ(k) are extrapolated to get the HD(k) and the impulse response hD(n) of the compensation filter is derived from normalized N-point Inverse DFT and applying window.

6. The receiver of claim 4, wherein the frequency-dependent mismatch estimation unit acquires the normalized value of time average of time-image correlation of signal output from the channelization filter normalized by average power of the signal output from the channelization filter by a pilot signal comprising SSB multitone.

7. A receiver comprising:
an I-branch comprising an I-branch mixer that down-converts a radio frequency signal to output an I-component, and an I-branch channelization filter that separates the baseband signal from the output signal of said I-branch mixer;
a Q-branch comprising a Q-branch mixer that down-converts the RF signal to output a Q component, and a Q-branch channelization filter that separates a baseband signal from an output signal of the Q-branch mixer;
a frequency-independent mismatch estimation unit that computes the frequency-independent mismatch of the I branch and the Q branch;
a frequency-independent mismatch compensation unit that compensates for frequency-independent mismatches of the I branch and the Q branch according to a computation result of the frequency-independent mismatch estimation unit.

8. The receiver of claim 7, wherein the frequency-independent mismatch estimator computes a gain mismatch and a phase mismatch of the I-branch mixer and the Q-branch mixer from a time average of the power of the output signals of the I-branch mixer and the Q-branch mixer normalized by a time average of the squared output signals of the I-branch mixer and Q-branch mixer.

9. The receiver of claim 7, wherein frequency-independence mismatch estimation unit estimates the gain mismatch (g_{RX}) and phase mismatch (θ_{RX}) by computing equation
$$\frac{E [ X ( k ) X ( - k ) ]}{E [ {\vert R ( k ) \vert}^{2} ]} = \frac{1 - {{g}_{RX}}^{2}}{1 + {{g}_{RX}}^{2}} - j \frac{2 {g}_{RX}}{1 + {{g}_{RX}}^{2}} sin {θ}_{RX} .$$
X(k): the output of the mixer in the discrete time domain, R(k): the input of the mixer in the discrete time domain.

10. The receiver of claim 9, wherein
The frequency-independent mismatch compensation unit comprises:
a first multiplier connected to the I branch,
a second multiplier connected to the Q branch,
a third multiplier that amplifies the output signal of the first multiplier, and
an adder that sums the output of the second multiplier with the output of the third multiplier.

11. The receiver of claim 10, wherein
a gain of the first multiplier corresponds to g_{RX},
a gain of the second multiplier corresponds to cos (1/θ_{RX}),
a gain of the third multiplier corresponds to tan (θ_{RX}). g_{RX}: gain mismatch, θ_{RX}: phase mismatch.
